(19) United States
(12) Patent Application Publication
(10) Pub. No.: US 2010/0132794 A1
(43) Pub. Date: Jun. 3, 2010

(54) SEALED PHOTOVOLTAIC APPARATUS

(76) Inventor: Brian H. Cumpston, Pleasanton, CA (US)

Correspondence Address: JONES DAY, 222 EAST 41ST ST, NEW YORK, NY, 10017, US

(21) Appl. No.: 12/444,583

(22) PCT Filed: Oct. 4, 2007
(86) PCT No.: PCT/US07/21492

§ 371 Date: Feb. 5, 2010

Related U.S. Application Data
(60) Provisional application No. 60/849,882, filed on Oct. 6, 2006.

(51) Int. Cl. H01L 31/0203; H01L 31/18

(52) U.S. Cl. 136/259; 438/64; 257/E31.117

(57) ABSTRACT

An assembly for producing photovoltaic electricity has an outer assembly having at least one portion transparent to light energy. The outer assembly defines an inner volume. The outer assembly can be made of a first structural member having an opening to an external environment, where the opening is defined by at least one edge. The outer assembly also has a second structural member with a recess that corresponds to the edge at the opening. In this manner the edge of the first structural member conjoins with the corresponding recess of the second structural member, and the edge is conjoined to the corresponding recess with a seal. One or more photovoltaic devices are disposed within the inner assembly volume. Each such photovoltaic device is operable to receive the light and produce photovoltaic electricity in response to it.

### CROSS-REFERENCE TO RELATED APPLICATIONS

This application claims priority to U.S. Provisional Patent Application No. 60/849,882, filed Oct. 6, 2006, which is hereby incorporated by reference herein in its entirety.

### FIELD

This application is directed to photovoltaic solar cell construction. In particular, it is directed to an environmentally sealed housing of a photovoltaic panel or module that surrounds the active photovoltaic device.

### BACKGROUND

FIG. 1 is a schematic block diagram of a conventional photovoltaic device. A photovoltaic module 10 can typically have one or more photovoltaic cells 12a-b disposed within it. A photovoltaic cell conventionally is made by having a semiconductor junction 14 disposed between a layer of conducting material 18 and a layer of transparent material 16.

The transparent material 16 can be a transparent conducting material that forms one side of a cathode/anode pair. Or, if the transparent material is not present, the cathode/anode can be formed directly on the semiconductor layer, such that light can pass between it.

In any event, light impinges upon the photovoltaic module 10 and transits through the transparent conducting material layer 16. Within semiconductor, the photons interact with the material to produce electron-hole pairs within the semiconductor junction layer 14. The semiconductor(s) typically is/are doped, thus creating an electric field extending from the junction layer 14. Accordingly, when the holes and/or electrons created by the sunlight in the semiconductor, they will migrate depending on the polarity of the device either to the transparent conducting material layer 16 or the conducting material layer 18. This migration creates current within the cell which is routed out of the cell for storage and/or instantaneous use.

One conducting node of the solar cell 12a is shown electrically coupled to an opposite node of another solar cell 12b by electrically conducting coupler 8. In this manner, the current created in one cell may be transmitted to another, where it is eventually collected. The currently depicted apparatus in FIG. 1 is shown where the solar cells are coupled in series, thus creating a higher voltage device. In another manner, (not shown) the solar cells can be coupled in parallel which increases the resulting current rather than the voltage. In any case, the current application is directed to any solar cell apparatus, whether they are electrically coupled in series, in parallel, or any combination thereof.

FIG. 2 is a schematic block diagram of a photovoltaic apparatus. The photovoltaic apparatus has a photovoltaic panel 20, which contains the active photovoltaic devices, such as those described supra (e.g., photovoltaic module 10). The photovoltaic panel 20 can be made up of one or multiple photovoltaic cells, photovoltaic modules, or other like photovoltaic devices, singly or multiples, solo or in combination with one another. A frame 22 surrounds the outer edge of the photovoltaic panel that houses the active photovoltaic devices. The frame 22 can be disposed flat or at an angle.

FIG. 3 is a side cross sectional view of the photovoltaic apparatus shown in FIG. 2. In this case, the cross section is taken along the line A-A shown above in FIG. 2. The photovoltaic panel has a photovoltaic device 50 (e.g. photovoltaic cell 12) disposed within frame 22. A glass, plastic, or other transparent barrier 26 is held by the frame 22 to shield the photovoltaic device 18 from an external environment. In some conventional photovoltaic apparatuses, a laminate layer 24 is placed between the photovoltaic device 50 and the transparent barrier 26.

Light impinges through the transparent barrier 26 and strikes the photovoltaic device 18. When the light strikes and is absorbed in the photovoltaic device 18, electricity can be generated much like as described with respect to FIG. 1.

Many solar cell junctions are sensitive to moisture. Over time, moisture and other portions of the external environment seeps into the solar cell assembly and causes the solar cell junction to corrode. While the transparent barrier 26 is designed to shield the photovoltaic device 18 from the effects of such an external environment, many times the protection afforded by the transparent barrier 26 is insufficient.

In many conventional photovoltaic panels, the transparent barrier 26 is wedged to the frame and bordered by a rubber gasket seal. One will realize that the transparent barrier 26 and the gasket seal do not typically truly isolate the interior of the apparatus from the external environment. In fact, the gasket will, even at the outset, leak an appreciable amount of the external environment into the volume defined by the frame 24 and the transparent barrier 26.

While the protection of such a seal can be marginally sufficient at the beginning of its life, the rubber seal will erode and/or decompose over time. Accordingly, greater portions of the external environment can impinge upon the semiconductor portion of the photovoltaic device 18 as time goes on, thus diminishing its performance.

In some conventional applications, a laminate 24 is placed between the photovoltaic solar device 50 and the transparent barrier 26. This laminate 24 can be heated so that it melts and affixes to the photovoltaic device 50 as well as the transparent barrier 26, providing a further environmental protection for the photovoltaic device 18.

One such type of laminate used in photovoltaic apparatuses is ethylene vinyl acetate (EVA). The EVA is applied to the active photovoltaic device, heated and then fused to the device and laminate materials under pressure. At a temperature at about 85° C., the EVA melts and flows into the volume about the photovoltaic device, and at approximately 120-125° C. the EVA starts to crosslink. In this manner, the transparent barrier 26 is sealed onto the solar cell using the EVA as the laminate 24.

Thus, the transparent barrier 26 in conjunction with the gasket attempt to act as a first defense of the assembly by preventing major excursions of the external environment into the volume defined by the transparent barrier 26 and the frame. The laminate can serve as an alternate line of protection apart from any gasket. In practice, the edge seal can be typically considered optional.

However, even with this dual-tier environmental defense, strong excursions of the external environment should be avoided, as one weak point in typical assembly design exists at the edges of the solar cell. In some cases, these edges have been coated with organic polymers in order to prevent moisture or other environmental contaminants from corroding the solar cell junction. Again, as in the case of the rubber gasket, while such organic polymers resist water, they are not impervious to water. Accordingly, again like the rubber gasket, environmental agents that make their way into the assembly volume can detrimentally affect the efficacy of this barrier over time, and, again over time, eventually degrade the solar cells.

It should be noted that the discussion above is in a general nature. Discussion or citation of a specific reference herein will not be construed as an admission that such reference is prior art to the present invention.

### BRIEF DESCRIPTION OF THE DRAWINGS

The accompanying drawings, which are incorporated into and constitute a part of this specification, illustrate one or more embodiments of the present invention and, together with the detailed description, serve to explain the principles and implementations of the invention.

In the drawings:

FIG. 1 is a schematic block diagram of a conventional photovoltaic device.

FIG. 2 is a schematic block diagram of a conventional photovoltaic apparatus.

FIG. 3 is a side cross sectional view of the photovoltaic apparatus shown in FIG. 2.

FIG. 4 is a slice schematic diagram of an exemplary photovoltaic apparatus.

FIG. 5 is a cross-sectional view of the photovoltaic apparatus of FIG. 3, along a longitudinal axis of the photovoltaic apparatus in FIG. 3.

FIG. 6a is a head-on view of the opening of the outer transparent barrier detailing the outline of the edge of the opening.

FIG. 6b is a head-on view of the cap detailing the recess that resides thereon.

FIG. 7 is a side cross-sectional view detailing a portion of a sealant material placed into the recess of the cap.

FIG. 8 is a side cross-sectional view detailing the sealant being heated and at least partially melted.

FIG. 9 is a side cross-sectional view detailing one embodiment in which the outer transparent barrier is brought into contact with the cap.

FIG. 10 is a side cross-sectional view detailing another embodiment in which the outer transparent barrier is brought into contact with the cap.

FIG. 11 is a cross-sectional view of another sealing embodiment.

FIG. 12 is a blow-up of the joint of the outer transparent barrier and frame of FIG. 3.

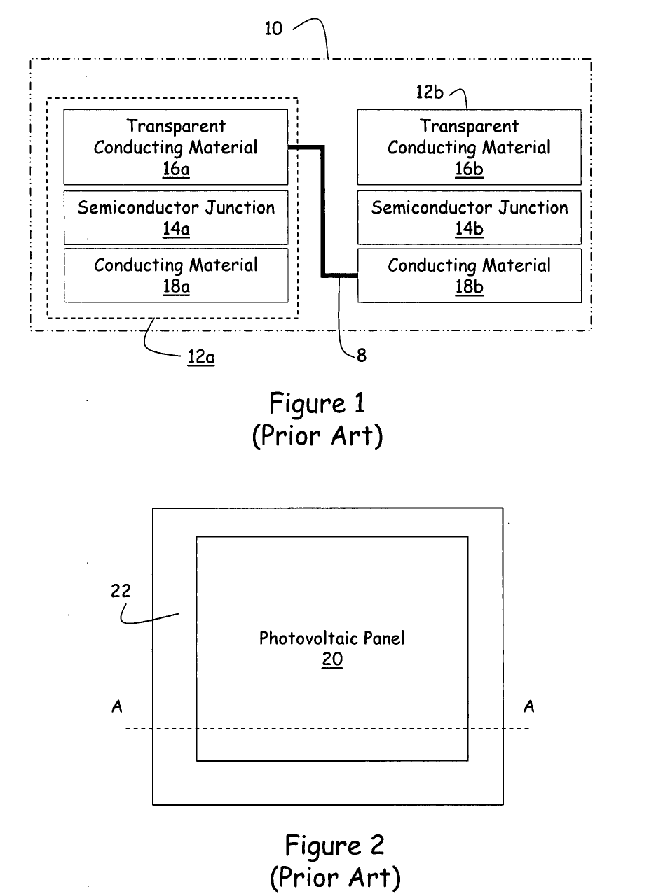

### DETAILED DESCRIPTION

Embodiments of the present invention are described herein in the context of a hermetically-sealed solar cell architecture using a molten glass frit. Those of ordinary skill in the art will realize that the following detailed description of the present invention is illustrative only and is not intended to be in any way limiting. Other embodiments of the present invention will readily suggest themselves to such skilled persons having the benefit of this disclosure. Reference will now be made in detail to implementations of the present invention as illustrated in the accompanying drawings. The same reference indicators will be used throughout the drawings and the following detailed description to refer to the same or like parts.

In the interest of clarity, not all of the routine features of the implementations described herein are shown and described. It will, of course, be appreciated that in the development of any such actual implementation, numerous implementation-specific decisions must be made in order to achieve the developer's specific goals, such as compliance with application- and business-related constraints, and that these specific goals will vary from one implementation to another and from one developer to another. Moreover, it will be appreciated that such a development effort might be complex and time-consuming, but would nevertheless be a routine undertaking of engineering for those of ordinary skill in the art having the benefit of this disclosure.

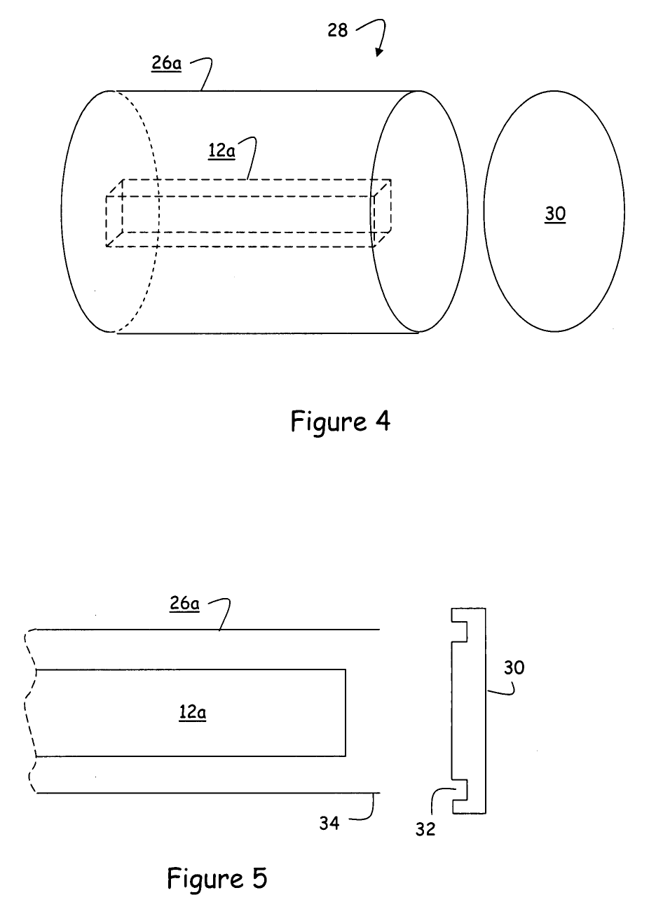

FIG. 4 is a slice schematic diagram of an exemplary photovoltaic apparatus. A photovoltaic apparatus 28 is depicted having a casing and a photovoltaic device disposed within the casing. In this particular case the photovoltaic device 12a is planar or rectangular nature, although it can be of any geometry. The photovoltaic device 12a resides within an outer transparent barrier 26a, which serves to at least partially surround the photovoltaic device 12a and protect it from the surrounding environment. While the outer transparent barrier 26a in this depiction is cylindrical in nature, again, any geometry may be used.

In some select embodiments, any of the photovoltaic devices disclosed herein include a rigid substrate. Rigidity of a material can be measured using several different metrics including, but not limited to, Young's modulus. In solid mechanics, Young's Modulus (E) (also known as the Young Modulus, modulus of elasticity, elastic modulus or tensile modulus) is a measure of the stiffness of a given material. It is defined as the ratio, for small strains, of the rate of change of stress with strain. This can be experimentally determined from the slope of a stress-strain curve created during tensile tests conducted on a sample of the material. Young's modulus for various materials is given in the following table.

| | Young's | |
|---|---|---|
| | modulus (E) in | Young's modulus |
| Material | GPa | (E) in lbf/in² (psi) |
| Rubber (small strain) | 0.01-0.1 | 1,500-15,000 |
| Low density polyethylene | 0.2 | 30,000 |
| Polypropylene | 1.5-2 | 217,000-290,000 |
| Polyethylene terephthalate | 2-2.5 | 290,000-360,000 |
| Polystyrene | 3-3.5 | 435,000-505,000 |
| Nylon | 3-7 | 290,000-580,000 |
| Aluminum alloy | 69 | 10,000,000 |
| Glass (all types) | 72 | 10,400,000 |
| Brass and bronze | 103-124 | 17,000,000 |
| Titanium (Ti) | 105-120 | 15,000,000-17,500,000 |
| Carbon fiber reinforced | 150 | 21,800,000 |
| plastic | | |
| (unidirectional, along grain) | | |
| Wrought iron and steel | 190-210 | 30,000,000 |
| Tungsten (W) | 400-410 | 58,000,000-59,500,000 |
| Silicon carbide (SiC) | 450 | 65,000,000 |
| Tungsten carbide (WC) | 450-650 | 65,000,000-94,000,000 |
| Single Carbon nanotube | 1,000+ | 145,000,000 |
| Diamond (C) | 1,050-1,200 | 150,000,000-175,000,000 |

In some embodiments of the present application, a material (e.g., a substrate of an active photovoltaic device) is deemed to be rigid when it is made of a material that has a Young's modulus of 20 GPa or greater, 30 GPa or greater, 40 GPa or greater, 50 GPa or greater, 60 GPa or greater, or 70 GPa or greater. In some embodiments of the present application a material (e.g., a substrate of an active photovoltaic device) is deemed to be rigid when the Young's modulus for the material is a constant over a range of strains. Such materials are called linear, and are said to obey Hooke's law. Thus, in some embodiments, a substrate of an active photovoltaic device is made out of a linear material that obeys Hooke's law. Examples of linear materials include, but are not limited to, steel, carbon fiber, and glass. Rubber and soil (except at very low strains) are non-linear materials. In some embodiments, a material is considered rigid when it adheres to the small deformation theory of elasticity, when subjected to any amount of force in a large range of forces (e.g., between 1 dyne and 10⁵ dynes, between 1000 dynes and 10⁶ dynes, between 10,000 dynes and 10⁷ dynes), such that the material only undergoes small elongations or shortenings or other deformations when subject to such force. The requirement that the deformations (or gradients of deformations) of such exemplary materials are small means, mathematically, that the square of either of these quantities is negligibly small when compared to the first power of the quantities when exposed to such a force. Another way of stating the requirement for a rigid material is that such a material, over a large range of forces, is well characterized by a strain tensor that only has linear terms. The strain tensor for materials is described in Borg, 1962, Fundamentals of Engineering Elasticity, Princeton, N.J., pp. 36-41. In some embodiments, a material is considered rigid when a sample of the material of sufficient size and dimensions does not bend under the force of gravity.

A cap 30 is provided to mate to the end of the outer open end of the transparent barrier 26a. When the cap 30 is conjoined to the outer transparent barrier 26a, this completes the seal of the photovoltaic apparatus, isolating the internal volume of the photovoltaic apparatus 28 from an external environment.

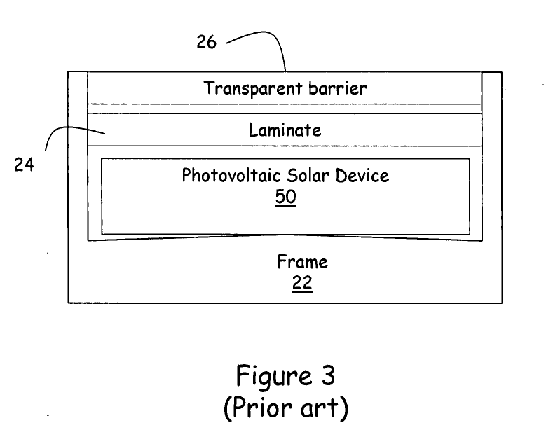

FIG. 5 is a cross-sectional view of the photovoltaic apparatus of FIG. 3, along a longitudinal axis of the photovoltaic apparatus in FIG. 3. The cap 30 has a recess or channel 32 within it that substantially conforms to a radial cross-sectional geometry of the outer transparent barrier 26a. In this manner, the cap 30, when placed in contact with the outer transparent barrier 26a, will both cover the opening of the outer transparent barrier 26a and have a contact with an edge 34. The contact between the cap 30 and the edge of the opening of the outer transparent barrier 26a takes place within the recess, so that the edge 34 of the outer transparent barrier 26a lies within the recess. When the edge 34 of the outer transparent barrier 26a is placed into the recess 32 of the cap 30, lateral movement of the cap 30 relative to the outer transparent barrier 26a can be restricted by the walls of the recess 32 disposed in the cap 30.

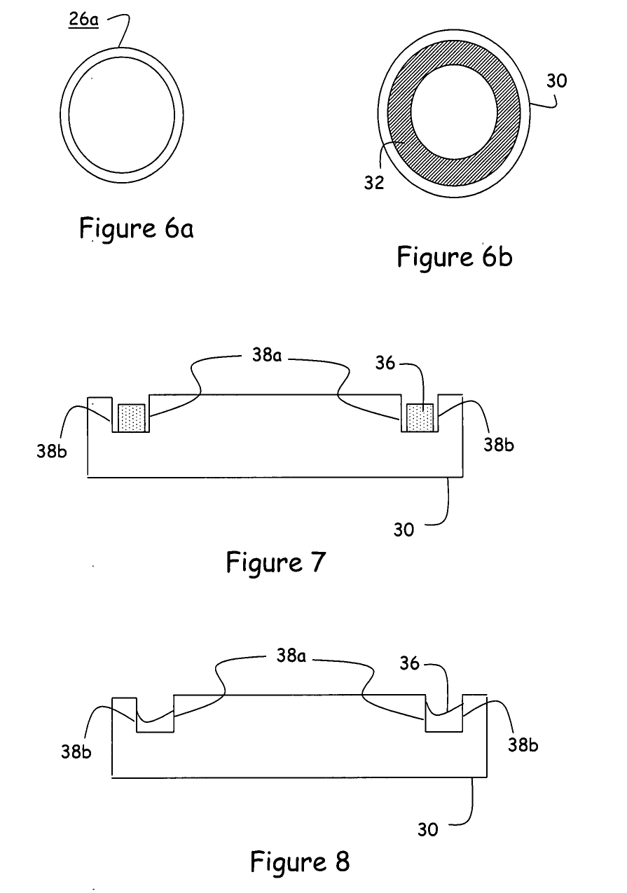

FIG. 6a is a head-on view of the opening of the outer transparent barrier 26a, detailing the outline of the edge of the opening. FIG. 6b is a head-on view of the cap 30 detailing the recess 32 that resides thereon. In this manner, it is shown that the outline of the edge of the opening of the outer transparent barrier 26a corresponds to the recess 32 disposed in the cap 30. It also serves to show that the opening of the outer transparent barrier 26a and the recess 32 of the cap 30 will fit together when placed into close proximity or contact with one another.

In FIG. 7, a portion of a sealant material 36 is placed into the recess of the cap 30, the recess being defined by the walls 38a-b of the cap 30. In one embodiment the sealant material can be a solid piece of glass, or flaked or powdered glass. Of course other sealant materials can be used.

In FIG. 8, the sealant 36 is heated and at least partially melts. Accordingly, the melted sealant 36 flows about in the recess of the cap 30.

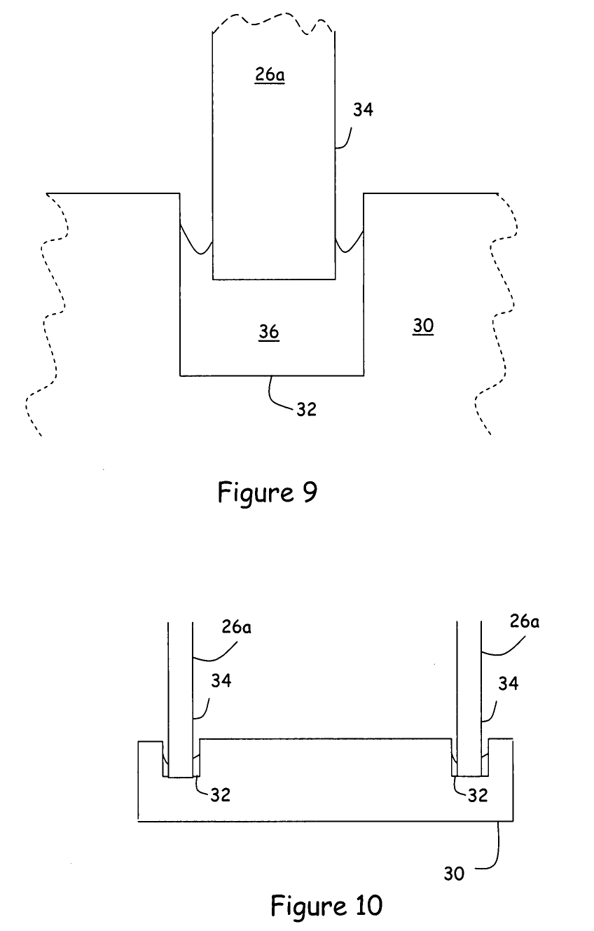

In FIG. 9, the outer transparent barrier 26a is brought into contact with the cap 30. The edge 34 of the outer transparent barrier 26a is brought into contact with melted sealant 36. Accordingly, when the edge 34 of the outer transparent barrier 26a encounters the melted sealant 36, the sealant flows around the edge 34.

In FIG. 10, the outer transparent barrier 26a is brought into full contact with the cap 30. When this happens, the sealant has been displaced within the recess. In particular, the sealant and has been displaced around both sides of the edges 34 of the outer transparent barrier 26a. In this manner, a dual-side seal is made about the outer transparent barrier 26a. This enables an environmental seal about the edges 34 of the outer transparent barrier 26a.

In one manner, the dual-sided seal substantially illustrated in FIG. 10 equalizes forces acting on the wall of the outer transparent barrier 26a. Thus, the life of the wall can be lengthened, since it will not be subject to greatly unequal stresses on either side, or in other words, experience tensile stress. In distinction, the described apparatus undergoes compressive stress due to the dual-sided seal.

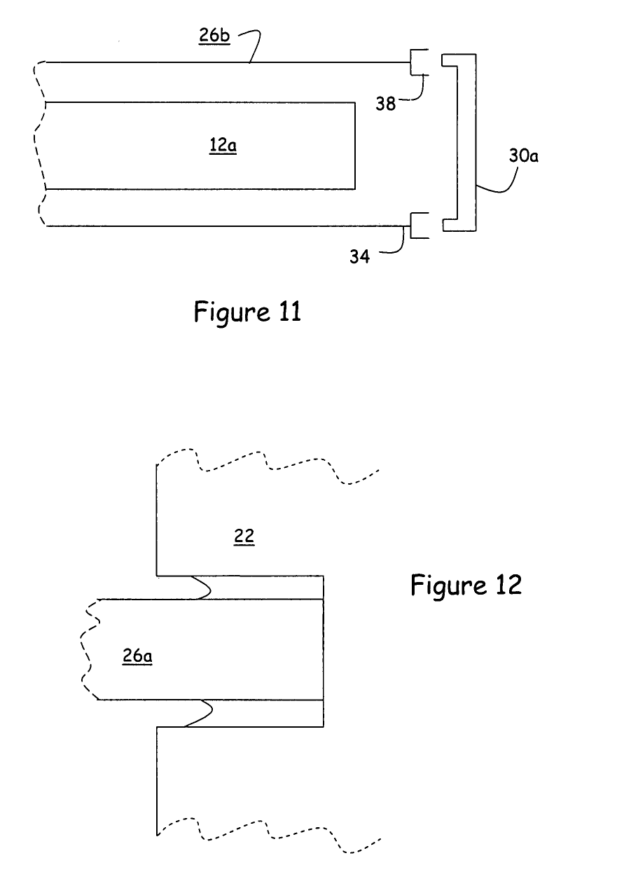

FIG. 11 is a cross-sectional view of an alternative embodiment. In this case, the walls of the outer transparent barrier 26b have a recess member 38 disposed on the end. The cap 30a has an end defined by an extended edge. The shape of the extended edge of the cap 30a corresponds to the shape of the recess member 38 on the outer transparent barrier 26b. In this case, the sealant is placed in the recessed member and at least partially melted. The extended edge of the cap 30a is placed into the recess member 38, thus forming the seal. In this manner, the process of mating an edge to a recess filled with a sealant can be accomplished, although the instrumentalities are reversed.

The apparatus need not be limited to unitary transparent or elongated casings, as previously shown. In fact, the dual-sided seal and the ability to form an environmental seal such as described can be applied to conventional photovoltaic assemblies. Take for example the apparatus as depicted in FIG. 2 and FIG. 3. The flat or planar-like outer transparent barrier 26 can be fitted to the frame much like as shown previously in the context of elongated and/or unitary outer transparent barriers of the Figures detailed.

FIG. 12 is a blow-up of the joint of the outer transparent barrier and frame of FIG. 3. In this manner, the outer transparent barrier 26 is fitted into a slot in the frame that contains the melted sealant. In this manner, the dual sided and fitted seal can be implemented in a conventional-appearing photovoltaic assembly. In the case that the outer transparent barrier 26 is glass and the frame 22 is metal, the assembly surrounds an inner volume protected by a glass-metal and/or glass-glass seal. Further, the seal is dual-sided with respect to the non-recess member. In terms of the planar or rectangular or omnifacial solar assembly, the recess member and the edge member may be reversed from FIG. 12 as depicted. In this case, the recess may occur on the outer transparent barrier 26, and the frame 22 can be characterized as having the extended edge.

The heating and melting of the sealant can be accomplished in many ways. The temperature can be increased to a value that will enable the sealant to soften and/or melt. Heat can be applied by methods such as direct contact with a hot surface, by inductively heating up a metal part, by contact with flame or hot air, or through absorption of light from a laser. In one embodiment, the sealant can be melted outside the recess, then added to the recess while in an at least partially molten stage.

In one embodiment, the sealant is glass. In another, the glass is vitreous in nature. Other potential sealants can include a metallic solder—that adheres to glass, other low-temperature melting point metals, or ceramics that have a high environmental sealant characteristic.

An outer transparent barrier 26, as depicted in the Figures, is any transparent barrier that seals a solar device and provides support and protection to the solar cell. The size and dimensions of outer transparent barrier 26a are determined by the size and dimension of individual device or devices housed within it. Outer transparent barrier 26a may be made of glass, plastic or any other suitable material. Examples of materials that can be used to make transparent tubular casing 310 include, but are not limited to, glass (e.g., soda lime glass, as an example), acrylics such as polymethylmethacrylate, polycarbonate, fluoropolymer (e.g., Tefzel or Teflon), polyethylene terephthalate (PET), Tedlar, or some other suitable transparent material.

In some specific embodiments, outer transparent barrier 26 is made of glass. The present invention contemplates a wide variety of glasses for transparent tubular or transparent elongated casing, some of which are described in this section and others of which are know to those of skill in the relevant arts. Common glass contains 20 about 70% amorphous silicon dioxide (SiO₂), which is the same chemical compound found in quartz, and its polycrystalline form, sand. In some embodiments, the properties of common glass are modified, or even changed entirely, with the addition of other compounds or heat treatment.

As previously mentioned, in some embodiments, outer transparent barrier 26 is made of clear plastic. Plastics can be a cheaper alternative to glass. However, plastic material is, in general, less stable under heat, has less favorable optical properties and does not prevent molecular water from penetrating through outer transparent barrier 26a. The last factor, if not rectified, can damage the photovoltaic devices and can substantially reduce their lifetime.

A wide variety of materials can be used in the production of outer transparent barrier 26, including, but not limited to, a urethane polymer, an acrylic polymer, polymethylmethacrylate (PMMA), a fluoropolymer, silicone, poly-dimethyl siloxane (PDMS), silicone gel, epoxy, ethyl vinyl acetate (EVA), perfluoroalkoxy fluorocarbon (PFA), nylon/polyamide, cross-linked polyethylene (PEX), polyolefin, polypropylene (PP), polyethylene terephtalate glycol (PETG), polytetrafluoroethylene (PTFE), thermoplastic copolymer (for example, ETFE®, which is a derived from the polymerization of ethylene and tetrafluoroethylene: TEFLON® monomers), polyurethane urethane, polyvinyl chloride (PVC), polyvinylidene fluoride (PVDF), Tygon®, Vinyl, and Viton®, or any combination or variation thereof.

The outer transparent barrier 26 can comprise a plurality of transparent tubular or transparent elongated casing layers. In some embodiments, each transparent tubular casing is composed of a different material.

The outer transparent barrier 26 can be of any geometry, although in this diagram it is cylindrical in nature. Other cross-sections of the outer barrier can be of any shape or any number of sides, including having a cross-section of any n-sided polygon. Such sides of a polygonal cross-section need not be congruent in length with one another. In particular, this can be applied generally elongated to multi-wall or (in the case of a purely arcuate barrier) omni-wall outer transparent barriers. Generally, the discussion can be applied to any transparent elongated casing that provides support and protection to solar cells. Even more generally, this specification should be considered as applying to the general rectangular construction of a conventional photovoltaic assembly. Accordingly, all these should be considered as within the scope of the systems and methods of the present disclosure.

The shape of the photovoltaic in the accompanying diagrams can be of any shape or size as long as it fits into a sleeve-like outer shell. In addition, although only one device is shown, the diagram and description should be construed to cover any number of photovoltaic devices within the sleeve-like outer shell.

Depending upon the materials used, helium leak rates of 10⁻⁹ cc/sec, 10⁻⁸ cc/sec, 10⁻⁷ cc/sec, 10⁻⁶ cc/sec, 10⁻⁵ cc/sec (all at standard pressure and temperature) can be achieved. Accordingly ranges of 10⁻⁵ cc/sec −10⁻⁷ cc/sec, 10⁻⁶ cc/sec −10⁻⁸ cc/sec, 10⁻⁷ cc/sec −10⁻⁹ cc/sec should all be considered as disclosed. A leak rate of less than 10⁻⁸ cc/sec. should be considered as a hermetic seal.

In some embodiments, the seal formed between sealant cap 30 and the wall of the outer transparent barrier 26a has a water vapor transmission rate (WVTR) of 10⁻⁴ g /m²·day or less. In some embodiments, the seal formed between sealant cap 30 and the wall of the outer transparent barrier 26a has a water vapor transmission rate (WVTR) of 10-5 g /m²·day or less. In some embodiments, the seal formed between sealant cap 30 and the wall of the outer transparent barrier 26a has a WVTR of 10-6 g/m²·day or less. In some embodiments, the seal formed between sealant cap 30 and the wall of the outer transparent barrier 26a has a WVTR of 10-7 g/m²·day or less. In some embodiments, the seal formed between sealant cap 30 and the wall of the outer transparent barrier 26a has a WVTR of 10-8 g/m²·day or less.

In some embodiments, the seal between sealant cap 30 and the wall 34 of outer transparent barrier 26a is accomplished using a glass, powder glass, or more generally, a ceramic material. In preferred embodiments, this glass or ceramic material has a melting temperature between 200° C. and 450° C. In embodiments, this glass or ceramic material has a melting temperature between 300° C. and 450° C. In embodiments, this glass or ceramic material has a melting temperature between 350° C. and 400° C.

An assembly for producing photovoltaic electricity is contemplated. The assembly is made of an outer assembly having at least one portion transparent to light energy, and defines an inner assembly volume. The outer assembly can be made of a first structural member having an opening to an external environment, where the opening is defined by at least one edge. The outer assembly also has a second structural member with a recess that corresponds to the edge at the opening. In this manner the edge of the first structural member conjoins with the corresponding recess of the second structural member, and the edge is conjoined to the corresponding recess with a seal. A photovoltaic device is disposed within the inner assembly volume. The photovoltaic device is operable to receive the light and produce electric energy in response to it.

The first structural member can be made with a transparent member. In one case, the first structural member is an elongated structure. In a more specific case the first structural member is a tubular structure. The first structural member can have an arcuate feature. Or, the first structural member can be characterized as having a cross-section of an n-sided polygon, where n is an integer greater than 2. The second structural member can be a metal cap.

The second structural member can be made with a transparent member. In one case, the second structural member is an elongated structure. In a more specific case the second structural member is a tubular structure. The second structural member can have an arcuate feature. Or, the second structural member can be characterized as having a cross-section of an n-sided polygon, where n is an integer greater than 2. The first structural member can be a metal cap.

An assembly for producing photovoltaic electricity can also be characterized as having an outer assembly having at least one portion transparent to light energy. The outer assembly can be characterized by having an end. The end can be characterized by an edge that bounds an opening, where the edge has at least a plurality of sides.

The assembly also has a cap characterized by having a recess disposed in its surface. The recess corresponds to the edge, where the cap is operable to fit to the elongated outer assembly by placing the edge within the recess.

The cap is affixed to the elongated outer assembly with a sealant, where the cap and elongated outer assembly define a hermetically sealed inner volume. A photovoltaic device is disposed within the inner volume.

In one case, the seal between the cap and the sealant is a glass to metal seal. The seal between the outer assembly and the sealant can be a glass to glass, seal.

In one case the outer assembly is characterized with a length and a width, where the length is at least three times the width of the outer assembly. The outer assembly can have an arcuate feature, or be a tubular structure. The outer assembly can also be characterized as having a cross-section of an n-sided polygon, where n is an integer greater than two.

An assembly for producing photovoltaic electricity is also considered. An elongated outer assembly having at least one portion transparent to light energy is provided. The outer assembly has an opening at the end, the opening characterized by an edge. The edge has at least a plurality of sides. The length of the outer assembly is substantially greater than a width of a cross-section of the outer assembly.

A cap having a recess disposed in its surface is also provided. The recess corresponds to the edge, and the cap is operable to fit to the elongated outer assembly by placing the edge within the recess. The cap is affixed to the elongated outer assembly with a sealant, thus forming a hermetically sealed inner volume. One or more photovoltaic devices are disposed within the inner volume, where the one or more photovoltaic devices are operable to receive the light and produce electric energy.

An assembly for producing photovoltaic electricity can be made with an outer assembly. The outer assembly has a first assembly member transparent to light energy. At the end of the outer assembly, an end structure is present that bounds an opening. A cap is provided to cover the opening.

A first structure is defined as one chosen from among the cap and the end structure. The first structure is characterized as having an edge.

A second structure is defined as the other of the cap and the end structure that is not the first structure. The second structure is characterized as having a recess disposed in it, where the recess corresponds in shape to an outline of the edge of the first structure.

The first structure is affixed to the second structure with a sealant affixed about the edge. The conjoined first structure and second structure define an inner volume. One or more photovoltaic devices are disposed within the inner volume.

The outer assembly can have a length substantially greater than a dimension of a cross-section of the outer assembly along its length. The outer assembly can comprise an arcuate feature. The outer assembly can have a polygonal cross-section.

In one case, the first structure is the end structure. In another, the first structure is the cap. The sealant can be glass.

A method of producing a photovoltaic assembly may include several steps. The method comprises a step of providing a storage member with an inner volume. The storage member has a photovoltaic device disposed within it, and an outer assembly with at least one wall. The outer assembly has an opening from an external environment to the inner volume.

Next, a sealing member is provided. A first member from either the storage member or the sealing member is characterized by a recess. A second member, being the other of the storage member or the sealing member, is characterized by an edge feature that corresponds in shape to the recess.

A sealing material is placed in the recess. The sealing material can be melted while in the recess, or it can be melted outside the recess and added to the recess. The sealant can be fully or partially melted.

The edge member is placed into the at least partially melted sealing material. Subsequent to placing the edge member into the sealing material, the sealing material is allowed to solidify about the edge member. This acts to seal the opening to the inner volume.

Thus, a photovoltaic apparatus having a hermetic seal is described and illustrated. Those skilled in the art will recognize that many modifications and variations of the present invention are possible without departing from the invention. Of course, the various features depicted in each of the figures and the accompanying text may be combined together.

Accordingly, it should be clearly understood that the present invention is not intended to be limited by the particular features specifically described and illustrated in the drawings, but the concept of the present invention is to be measured by the scope of the appended claims. It should be understood that various changes, substitutions, and alterations could be made hereto without departing from the spirit and scope of the invention as described by the appended claims that follow.

While embodiments and applications of this invention have been shown and described, it would be apparent to these skilled in the art having the benefit of this disclosure that many more modifications than mentioned above are possible without departing from the inventive concepts herein. The invention, therefore, is not to be restricted except in the spirit of the appended claims.

1. An assembly for producing electricity, the assembly comprising:
an outer assembly having at least one portion transparent to light energy and defining an inner assembly volume, the outer assembly comprising:
a first structural member with an opening to an external environment, the opening defined by at least one edge; and
a second structural member, with a recess corresponding to the at least one edge;
wherein the at least one edge of the first structural member conjoins with the corresponding recess of the second structural member;
and wherein the at least one edge is conjoined to the corresponding recess by a seal; and
one or more photovoltaic devices disposed within the inner assembly volume, wherein a photovoltaic device in the one or more photovoltaic devices is operable to receive the light and produce electricity in response thereto, and wherein said photovoltaic device includes a rigid substrate.

2. The assembly of claim 1, wherein the first structural member comprises at least in part a transparent member.

3. The assembly of claim 1 or 2, wherein the first structural member is elongated.

4. The assembly of claim 1, wherein the first structural member is tubular.

5. The assembly of claim 1, wherein the first structural member has an arcuate feature.

6. The assembly of claim 1, wherein the first structural member is characterized as having a cross-section of an n-sided polygon, where n is an integer greater than two.

7. The assembly of claim 1, wherein the second structural member is a metal cap.

8. The assembly of claim 1, wherein the second structural member comprises at least in part a transparent member.

9. The assembly of claim 1, wherein the second structural member is elongated.

10. The assembly of claim 1, wherein the second structural member is tubular.

11. The assembly of claim 1, wherein the second structural member has an arcuate feature.

12. The assembly of claim 1, wherein the second structural member is characterized as having a cross-section of an n-sided polygon, where n is an integer greater than two.

13. The assembly of claim 1, wherein the first structural member is a metal cap.

14. The assembly of claim 1, wherein
the first structural member comprises at least in part a transparent member;
the first structural member is an elongated tube; and
the second structural member is a metal cap.

15. The assembly of claim 1, wherein
the second structural member comprises at least in part a transparent member;
the second structural member is an elongated tube; and
the first structural member is a metal cap.

16. The assembly of claim 1, wherein the outer assembly has a helium leak rate of 10⁻⁶ cc/sec or less.

17. The assembly of claim 1, wherein the outer assembly has a helium leak rate of 10⁻⁸ cc/sec or less.

18. An assembly for producing electricity, the assembly comprising:
an outer assembly having at least one portion transparent to light energy, the outer assembly characterized by having an end, the end characterized by an edge that bounds an opening, the edge having at least a plurality of sides;
a cap having a recess disposed in its surface, the recess corresponding to the edge, wherein the cap is operable to fit to the elongated outer assembly by placing the edge within the recess;
the cap being affixed to the outer assembly with a sealant, the cap and elongated outer assembly defining a hermetically sealed inner volume; and
one or more photovoltaic devices disposed within the inner volume, wherein a photovoltaic device in the one or more photovoltaic devices is operable to receive the light and produce electricity in response thereto, and wherein said photovoltaic device includes a rigid substrate.

19. The assembly of claim 18, wherein the seal between the cap and the sealant is a glass to metal seal.

20. The assembly of claim 18 or 19, wherein the outer assembly is characterized by a length and a width, wherein the length is at least three times the width of the outer assembly.

21. The assembly of claim 18, wherein the seal between the outer assembly and the sealant is a glass to glass seal.

22. The assembly of claim 18, wherein the outer assembly is a tubular structure.

23. The assembly of claim 18, wherein the outer assembly has an arcuate feature.

24. The assembly of claim 18, wherein the outer assembly is characterized as having a cross-section of an n-sided polygon, where n is an integer greater than two.

25. The assembly of claim 18, wherein the outer assembly has a helium leak rate of 10⁻⁶ cc/sec or less.

26. The assembly of claim 18, wherein the outer assembly has a helium leak rate of 10⁻⁸ cc/sec or less.

27. An assembly for producing electricity, the assembly comprising:
an outer assembly having at least one portion transparent to light energy, the outer assembly characterized by having an end, the end characterized by an edge that bounds an opening, the edge having at least a plurality of sides;
a cap having a recess disposed in its surface, the recess corresponding to the edge, wherein the cap is operable to fit to the elongated outer assembly by placing the edge within the recess;
the cap being affixed to the elongated outer assembly with a sealant, the cap and elongated outer assembly defining a hermetically sealed inner volume; and
one or more photovoltaic devices disposed within the inner volume, wherein a photovoltaic device in the one or more photovoltaic devices is operable to receive the light and produce electricity in response thereto, wherein said photovoltaic device includes a rigid substrate; and wherein
the length of the outer assembly is substantially greater than a width of a cross-sectional of the outer assembly.

28. An assembly for producing electricity, the assembly comprising:
an outer assembly, wherein at least a portion of the outer assembly is transparent to light energy, the outer assembly comprising:
an end structure, at an end of the outer assembly, having an opening bounded by at least one wall of the elongated outer assembly;
a cap operable to cover the opening;
a first structure, chosen from among the cap and the end structure, characterized as having an edge;
a second structure, which is not the first structure, chosen from among the cap and the end structure, characterized as having a recess disposed in it, the recess corresponding in shape to an outline of the edge of the first structure;
the first structure being affixed to the second structure with a sealant affixed about a plurality of sides associated with the edge, the conjoined first structure and second structure defining an inner volume; and
one or more photovoltaic devices disposed within the inner volume, wherein a photovoltaic device in the one or more photovoltaic devices is operable to receive the light and produce electricity in response thereto, and wherein said photovoltaic device includes a rigid substrate.

29. The assembly of claim 28, wherein the outer assembly has a length substantially greater than a dimension of a cross-section of the outer assembly taken at a point along the length of the outer assembly.

30. The assembly of claim 28 or 29, wherein the outer assembly comprises an arcuate feature.

31. The assembly of claim 28, wherein the outer assembly comprises an arcuate feature.

32. The assembly of claim 28, wherein the outer assembly has a polygonal cross-section.

33. The assembly of claim 28, wherein the first structure is the end structure.

34. The assembly of claim 28, wherein the first structure is the cap.

35. The assembly of 28, wherein the sealant is glass.

36. The assembly of claim 28, wherein the outer assembly has a helium leak rate of 10⁻⁶ cc/sec or less.

37. The assembly of claim 28, wherein the outer assembly has a helium leak rate of 10⁻⁸ cc/sec or less.

38. An assembly for producing electricity, the assembly comprising:
an elongated outer assembly, the outer assembly having a length substantially greater than a dimension of a cross-section of the outer assembly along its length, wherein at least a portion of the elongated outer assembly is transparent to light energy, the outer assembly comprising:
an end structure, at an end of the outer assembly, having an opening bounded by at least one wall of the elongated outer assembly;
a cap operable to cover the opening;
a first structure, chosen from among the cap and the end structure, characterized as having an edge;
a second structure, which is not the first structure, chosen from among the cap and the end structure, characterized as having a recess disposed in it, the recess corresponding in shape to an outline of the edge of the first structure;
the first structure being affixed to the second structure with a sealant affixed about both sides of the edge, the conjoined first structure and second structure defining an inner volume;
one or more photovoltaic devices disposed within the inner assembly volume, wherein a photovoltaic device in the one or more photovoltaic devices is operable to receive the light and produce photovoltaic electricity in response thereto, and wherein said photovoltaic device includes a rigid substrate.

39. A method of producing a photovoltaic assembly, the method comprising:
(A) providing a storage member, the storage member comprising:
an outer assembly with at least one wall, the at least one wall defining an inner volume, the outer assembly having an opening from an external environment to the inner volume, the opening defined with an edge, the edge characterized by a plurality of sides; and
one or more photovoltaic devices within the inner volume wherein a photovoltaic device in the one or more photovoltaic devices is operable to receive the light and produce photovoltaic electricity in response thereto, and wherein said photovoltaic device includes a rigid substrate;
(B) providing a sealing member that covers said opening;
wherein a first member from either the storage member or the sealing member is characterized by a recess;
wherein a second member, being another member from either the storage member or the sealing member aside from the first member, is characterized by an edge feature, the edge feature corresponding in shape to the recess;
(C) placing a sealing material in the recess;
(D) melting at least a portion of the sealing material in the recess;
(E) placing the edge member into the at least partially melted sealing material;
subsequent to the act of placing the edge member into the sealing material, allowing the sealing material to solidify about the edge member;
the step of placing the edge into the at least partially melted sealing material and the step of allowing the sealing material to solidify about the edge member acting to seal the opening to the inner volume.

40. The rigid substrate of any one of claims 1, 18, 27, 28, 38 and 39, wherein said rigid substrate has a Young's modulus of 20 GPa or greater.

41. The rigid substrate of any one of claims 1, 18, 27, 28, 38 and 39, wherein said rigid substrate has a Young's modulus of 50 GPa or greater.
